(19) United States
(12) Patent Application Publication
(10) Pub. No.: US 2024/0234520 A9
(43) Pub. Date: Jul. 11, 2024

(54) LATERALLY DIFFUSED METAL OXIDE SEMICONDUCTOR DEVICE AND PREPARATION METHOD THEREFOR

(71) Applicant: CSMC TECHNOLOGIES FAB2 CO., LTD., WUXI NEW DISTRICT, JIANGSU (CN)

(72) Inventors: CHUNXU LI, WUXI NEW DISTRICT, JIANGSU (CN); FENG LIN, WUXI NEW DISTRICT, JIANGSU (CN); SHUXIAN CHEN, WUXI NEW DISTRICT, JIANGSU (CN); HONGFENG JIN, WUXI NEW DISTRICT, JIANGSU (CN); HUAJUN JIN, WUXI NEW DISTRICT, JIANGSU (CN); GANG HUANG, WUXI NEW DISTRICT, JIANGSU (CN); YU HUANG, WUXI NEW DISTRICT, JIANGSU (CN); BIN YANG, WUXI NEW DISTRICT, JIANGSU (CN)

(73) Assignee: CSMC TECHNOLOGIES FAB2 CO., LTD., WUXI NEW DISTRICT, JIANGSU (CN)

(21) Appl. No.: 18/277,658

(22) PCT Filed: Jul. 28, 2021
(86) PCT No.: PCT/CN2021/108936

§ 371 Date: Aug. 17, 2023

(30) Foreign Application Priority Data
Feb. 18, 2021 (CN) 202110187733.0

(51) Int. Cl. H01L 29/40; H01L 29/06; H01L 29/66; H01L 29/78

(52) U.S. Cl. CPC H01L 29/402; H01L 29/0653; H01L 29/401; H01L 29/66681; H01L 29/7816

(57) ABSTRACT

A laterally diffused metal oxide semiconductor device and a preparation method thereof are disclosed. The semiconductor device includes: a substrate; a body region having a first conductivity type and formed in the substrate; a drift region, having a second conductivity type, formed in the substrate and adjacent to the body region; a field plate structure, formed on the drift region, a lower surface of an end of the field plate structure close to the body region being flush with the upper surface of the substrate, and the end of the field plate structure close to the body region also having an upwardly extending inclined surface; and a drain region, having a second conductivity type, formed in an upper layer of the drift region, and in contact with the end of the field plate structure away from the body region.

### TECHNICAL FIELD

The present disclosure relates to the field of semiconductor technology, and in particular, to a laterally diffused metal oxide semiconductor device and a preparation method therefor.

### BACKGROUND

N-type laterally diffused metal oxide semiconductors (NLDMOS) are core devices in bipolar-CMOS-DMOS (BCD) technology. Breakdown voltage and on-resistance are the main indicators to measure the performance of LDMOS devices. In order to ensure that LDMOS devices have sufficiently high breakdown voltage and sufficiently low on-resistance, it is necessary to modulate the impurity distribution of the drift region used for voltage resistance and to modulate the field plate structure. In typical process technology, local oxidation of silicon (LOCOS) structures or shallow trench isolation (STI) structures are usually used for longitudinal voltage-resistant field plates. By modulating the thickness and length of the field plate structure, the performance of LDMOS devices can be achieved as expected.

For LDMOS devices, in order to improve the electric field distribution and increase the reliability of the device, a field plate with a gradual thickness needs to be formed. That is, a field plate is required near the junction field-effect transistor (JFET) region of the device, and the thickness of the field plate at this position should be less than that at the drift region. Although a field plate with a LOCOS structure can have a large “bird's beak” and can serve as a field plate whose thickness at the JEFET region is less than that at the drift region, the presence of a long bird's beak of the LOCOS structure will increase the pitch of the entire LDMOS device and increase the on-resistance of the device.

### SUMMARY

The present disclosure provides a laterally diffused metal oxide semiconductor device, which includes a substrate, a body region, a drift region, a field plate structure, and a drain region.

The body region has a first conductivity type and is formed in the substrate.

The drift region has a second conductivity type, is formed in the substrate and is adjacent to the body region. The second conductivity type is opposite to the first conductivity type.

The field plate structure is formed on the drift region. The lower surface of an end of the field plate structure near the body region is flush with the upper surface of the substrate, and the end of the field plate structure near the body region also has an upwardly extending inclined surface. The lower surface of an end of the field plate structure away from the body region is lower than the upper surface of the substrate. The thickness of the field plate structure gradually increases to a preset value from the end near the body region to the end far from the body region.

The drain region has a second conductivity type, is formed in the upper layer of the drift region and is in contact with the end of the field plate structure away from the body region.

In an embodiment, the angle φ between the inclined surface and the lower surface of the end of the field plate structure near the body region is not less than 30 degrees and not more than 60 degrees.

In an embodiment, the field plate structure includes a first oxide structure and a second oxide structure.

The first oxide structure is an end of the field plate structure close to the drain region and formed on the drift region. The upper surface of the first oxide structure is not lower than the upper surface of the substrate. Along the direction from the body region to the drift region, the first oxide structure sequentially includes a first end portion and a second end portion. The thickness of the first oxide structure gradually increases to a preset value from the first end portion toward the second end portion.

The second oxide structure is formed on the upper surface of the drift region on the side close to the body region, and extends along the upper surface of the first end portion to the junction of the first end portion and the second end portion. The inclined surface is the upper surface of an end of the second oxide structure near the body region.

In an embodiment, the thickness of the second oxide structure is not greater than 1500 Å.

In an embodiment, the first oxide structure includes a local silicon isolation oxide structure, which is made by a recess process.

In an embodiment, the laterally diffused metal oxide semiconductor device further includes a source region, a polysilicon gate, and shallow trench isolation structures.

The source region has a second conductivity type, and is formed in the upper layer of the body region.

The polysilicon gate is formed on the field plate structure and extends along the field plate structure to cover the substrate between the source region and the field plate structure.

The shallow trench isolation structures are formed in the substrate. One of the shallow trench isolation structures is in contact with the drain region, and a portion of the lower surface of this shallow trench isolation structure is in contact with the drift region.

In the above laterally diffused metal oxide semiconductor device, a field plate structure is formed on the drift region. The lower surface of an end of the field plate structure near the body region is flush with the upper surface of the substrate, and the end of the field plate structure near the body region also has an upwardly extending inclined surface. The lower surface of an end of the field plate structure away from the body region is lower than the upper surface of the substrate. The thickness of the field plate structure gradually increases to a preset value from the end near the body region to the end away from the body region. By providing a field plate structure with the end near the body region having a lower surface flush with the upper surface of the substrate and having an upwardly extending inclined surface, and gradually increasing the thickness of the field plate structure to a preset value from the end near the body region to the end away from the body region, a field plate structure with gradually increasing thickness is formed at the position of the JFET region without increasing the length of the field plate structure whose lower surface is below the upper surface of the substrate (without increasing the pitch of the LDMOS device), thus improving the reliability of the device while improving the electric field distribution on the device surface.

The present disclosure also provides a method for preparing a laterally diffused metal oxide semiconductor device, and the method includes: providing a substrate; forming a body region and a drift region that are adjacent to each other in the substrate, the body region having a first conductivity type, and the drift region having a second conductivity type opposite to the first conductivity type; forming a field plate structure on the drift region, the lower surface of an end of the field plate structure near the body region being flush with the upper surface of the substrate, and the end of the field plate structure near the body region having an upwardly extending inclined surface, the lower surface of an end of the field plate structure away from the body region being lower than the upper surface of the substrate, and the thickness of the field plate structure gradually increasing to a preset value from the end near the body region to the end away from the body region; and forming a drain region of a second conductivity type in the upper layer of the drift region, and the drain region being in contact with the end of the field plate structure away from the body region.

In an embodiment, the forming of the field plate structure on the drift region includes: forming a first oxide structure on the drift region, the first oxide structure sequentially including a first end portion and a second end portion along the direction from the body region to the drift region, and the thickness of the first oxide structure gradually increasing to a preset value from the first end portion toward the second end portion; and forming a second oxide structure on the upper surface of the drift region on the side close to the body region, the second oxide structure extending along the upper surface of the first end portion to the junction of the first end portion and the second end portion.

The first oxide structure is the end of the field plate structure away from the body region. The inclined surface is the upper surface of an end of the second oxide structure close to the body region. The angle between the inclined surface and the lower surface of the end of the field plate structure near the body region is not less than 30 degrees and not more than 60 degrees.

In an embodiment, the first oxide structure includes a local silicon isolation oxide structure, and the forming of the first oxide structure on the drift region includes: forming a hard mask layer on the substrate, and providing a groove in the hard mask layer, the groove exposing the substrate where the predetermined area of the first oxide structure is located; forming a sidewall structure on the side wall of the groove, the sidewall structure being in contact with the hard mask layer, and the lower surface of the sidewall structure being flush with the bottom of the groove; and forming the first oxide structure at the bottom of the groove by performing a local thermal oxidation process.

In an embodiment, the forming of the second oxide structure on the upper surface of the drift region on the side close to the body region includes: forming an oxide film on the upper surface of the substrate; forming a photoresist mask layer on the oxide film, the photoresist mask layer covering the oxide film where a predetermined region of the second oxide structure is located; and removing the excess oxide film by performing a wet etching process, to obtain the second oxide structure consisting of the remaining oxide film in the predetermined region of the second oxide structure.

In an embodiment, the oxide film has a thickness of not less than 300 Å and not greater than 1500 Å.

In an embodiment, the method for preparing the laterally diffused metal oxide semiconductor device further includes: forming shallow trench isolation structures in the substrate, one of the shallow trench isolation structures being in contact with the drain region, and a portion of the lower surface of this shallow trench isolation structure is in contact with the drift region; forming a source region with a second conductivity type in the upper layer of the body region; and forming a polysilicon gate on the field plate structure, the polysilicon gate extending along the field plate structure to cover a portion of the substrate between the source region and the field plate structure.

In the above method for preparing a laterally diffused metal oxide semiconductor device, a field plate structure is formed on the drift region. The lower surface of an end of the field plate structure near the body region is flush with the upper surface of the substrate, and the end of the field plate structure near the body region also has an upwardly extending inclined surface. The lower surface of an end of the field plate structure away from the body region is lower than the upper surface of the substrate. The thickness of the field plate structure gradually increases to a preset value from the end near the body region to the end far from the body region. By forming a field plate structure with the end near the body region having a lower surface flush with the upper surface of the substrate and having an upwardly extending inclined surface, and gradually increasing the thickness of the field plate structure to a preset value from the end near the body region to the end away from the body region, a field plate structure with gradually increasing thickness is formed at the position of the JFET region without increasing the length of the field plate structure whose lower surface is below the upper surface of the substrate (without increasing the pitch of the LDMOS device), thus improving the reliability of the device while improving the electric field distribution on the device surface.

### BRIEF DESCRIPTION OF THE DRAWINGS

To better illustrate the technical solutions of the embodiments of the present disclosure or of the prior art, the following will briefly introduce the drawings required for the description of embodiments or prior art. Obviously, the drawings in the following description are some embodiments of the present disclosure. For those of ordinary skill in the art, other drawings may be obtained based on these drawings without creative efforts.

FIG. 1 is a flow chart showing a method for preparing a laterally diffused metal oxide semiconductor device according to an embodiment of the present disclosure.

FIG. 2 is a schematic diagram showing a process of forming a field plate structure on a drift region according to an embodiment of the present disclosure.

FIG. 3 is a schematic diagram showing a process of forming a first oxide structure on a drift region according to an embodiment of the present disclosure.

FIG. 4 is a cross-sectional view of a device in an embodiment in which a hard mask layer has been formed on a substrate.

FIG. 5 is a cross-sectional view of a device in an embodiment in which a sidewall structure has been formed.

FIG. 6 is a cross-sectional view of a device in an embodiment in which a first oxide structure has been formed.

FIG. 7 is a cross-sectional view of a device in an embodiment in which a photoresist mask layer has been formed.

FIG. 8 is a cross-sectional view of a device in an embodiment in which a second oxide structure has been formed.

### DETAILED DESCRIPTION

To facilitate understanding of the present disclosure, a more comprehensive description of the present disclosure will be given below with reference to the relevant figures. Embodiments of the present disclosure are given in the accompanying drawings. However, the present disclosure can be implemented in many different forms and is not limited to the embodiments described herein. Instead, the purpose of providing these embodiments is to make the disclosure of the invention more thorough and comprehensive.

Unless otherwise defined, all technical and scientific terms used herein have the same meaning as commonly understood by those skilled in the art to which the present disclosure belongs. The terms used in this specification are for the purpose of describing specific embodiments only and are not intended to limit the present disclosure.

It should be understood that when an element or layer is referred to as being “on,” “adjacent to,” “connected to,” or “coupled to” another element or layer, it may be directly on, adjacent to, connected or coupled to the other element or layer, or there may be intervening elements or layers between them. In contrast, when an element is referred to as being “directly on,” “directly adjacent to,” “directly connected to,” or “directly coupled to” another element or layer, there are no intervening elements or layers between them. It should be understood that although terms such as first, second, third, etc. may be used herein to describe various elements, components, regions, layers, doping types and/or sections, these elements, components, regions, layers, doping types and/or sections should not be limited by these terms. These terms are only used to distinguish one element, component, region, layer, doping type or section from another element, component, region, layer, doping type or section. Thus, a first element, component, region, layer, doping type or section discussed below may be denoted as a second element, component, region, layer, doping type or section without departing from the teachings of the present disclosure. For example, a first doping type may be denoted as a second doping type, and similarly, a second doping type may be denoted as a first doping type. The first doping type and the second doping type are different doping types, for example, it may be that the first doping type is P-type and the second doping type is N-type, or that the first doping type is N-type and the second doping type is P-type.

Spatial relationship terms such as “under”, “below”, “lower”, “beneath”, “above”, “upper”, etc., can be used herein to facilitate the description of the relationship between one element or feature and another element or feature shown in the figures. It should be understood that in addition to the orientations shown in the figures, the spatial relationship terms also include different orientations of the device in actual use and operation. For example, a component that is described as “below” other components is described as “above” other components if the device in the drawings is turned over. Therefore, the exemplary terms “below” and “under” can include both “above” and “below” orientations. In addition, the device can also include other orientations (such as rotating 90 degrees or other orientations), and the spatial description language used herein should be interpreted accordingly.

As used herein, the singular forms “one”, “a” and “said/that” may also include the plural forms, unless the context clearly indicates otherwise. It should also be understood that the terms “comprise/include” or “have” specify the presence of stated features, integers, steps, operations, elements, parts or combinations thereof, but do not preclude the presence or addition of one or more other features, integers, steps, operations, elements, parts or combinations thereof. Also, in this specification, the term “and/or” includes any and all combinations of the relevant listed items.

Embodiments of the present disclosure are described herein with reference to cross-sectional views as a schematic representation of an ideal embodiment (and intermediate structure) of the present disclosure, so that variations in the shape due, for example, to manufacturing techniques and/or tolerances can be expected. Accordingly, embodiments of the present disclosure should not be limited to the particular shape of the region shown herein, but include deviations in shape due to, for example, manufacturing techniques. For example, an implanted region illustrated as a rectangle will, typically, have rounded or curved features and/or a gradient of implant concentration at its edges rather than a discrete change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of present disclosure.

For LDMOS devices, it is desirable that a certain field plate thickness exists near the JFET region, for improving the electric field distribution and to enhance the reliability of the LDMOS device. The thickness of the field plate near the JFET region needs to be less than the thickness of the field plate at the drift region and greater than the thickness of the oxide layer of the gate oxide layer. If a field plate of STI structure is used, it is not possible to prepare the field plate with a slow change in thickness by a single process. If a field plate of LOCOS structure is used, although the LOCOS structure with a large “bird's beak” can be prepared by a single process and the field plate with a slow change in thickness can be obtained, the too long bird's beak will affect the pitch of the whole LDMOS device and lead to a large on-resistance of the device.

Refer to FIG. 1, which is a flow chart showing a method for manufacturing a laterally diffused metal oxide semiconductor device according to an embodiment of the present disclosure.

As shown in FIG. 1, the present disclosure provides the method for preparing the laterally diffused metal oxide semiconductor device, and the method includes:

S102, a substrate is provided.

The substrate may include undoped single monocrystalline silicon, impurity-doped monocrystalline silicon, silicon on insulator (SOI), stacked silicon on insulator (SSOI), stacked silicon germanium on insulator (S—SiGeOI), silicon germanium on insulator (SiGeOI), and germanium on insulator (GeOI). As an example, the material of the substrate is monocrystalline silicon.

S104, a body region and a drift region that are adjacent to each other are formed in the substrate.

The body region has a first conductivity type, and the drift region has a second conductivity type opposite to the first conductivity type. When the first conductivity type is P type, the second conductivity type is N type; when the first conductivity type is N type, the second conductivity type is P type. In this embodiment, the first conductivity type is P type, and the second conductivity type is N type.

S106, a field plate structure is formed on the drift region.

The lower surface of an end of the field plate structure near the body region is flush with the upper surface of the substrate, and the end of the field plate structure near the body region also has an upwardly extending inclined surface. The lower surface of an end of the field plate structure away from the body region is lower than the upper surface of the substrate. The thickness of the field plate structure gradually increases to a preset value from the end near the body region to the end away from the body region.

S108, a drain region of a second conductivity type is formed in the upper layer of the drift region, and the drain region is in contact with the end of the field plate structure away from the body region.

In the above method for preparing the laterally diffused metal oxide semiconductor device, a field plate structure is formed on the drift region. The lower surface of an end of the field plate structure near the body region is flush with the upper surface of the substrate, and the end of the field plate structure near the body region also has an upwardly extending inclined surface. The lower surface of an end of the field plate structure away from the body region is lower than the upper surface of the substrate. The thickness of the field plate structure gradually increases to a preset value from the end near the body region to the end away from the body region. By forming a field plate structure with the end near the body region having a lower surface flush with the upper surface of the substrate and having an upwardly extending inclined surface, and gradually increasing the thickness of the field plate structure to a preset value from the end near the body region to the end away from the body region, a field plate structure with gradually increasing thickness is formed at the position of the JFET region without increasing the length of the field plate structure whose lower surface is below the upper surface of the substrate (without increasing the pitch of the LDMOS device), thus improving the reliability of the device while improving the electric field distribution on the device surface.

In an embodiment, the order of steps S104 and S106 can be adjusted according to actual needs, for example, step S104 is performed first and then step S106 is performed, or step S106 is performed first and then step S104 is performed. As an example, step S104 is performed first, followed by step S106.

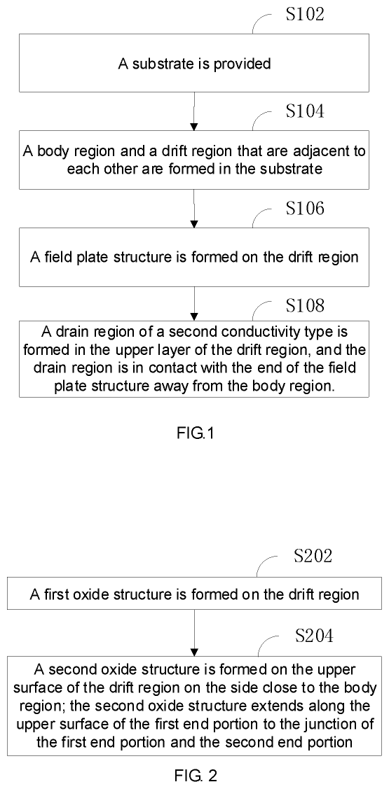

FIG. 2 is a schematic diagram showing the process of forming a field plate structure on a drift region according to an embodiment.

As shown in FIG. 2, S106 includes:

S202, a first oxide structure is formed on the drift region.

The first oxide structure includes a first end portion and a second end portion in order along the direction from the body region toward the drift region. The thickness of the first oxide structure gradually increases to a preset value from the first end portion toward the second end portion. The first oxide structure is a portion of the field plate structure at an end away from the body region and whose lower surface is not higher than the upper surface of the substrate.

In an embodiment, before step S104 is performed, the method further includes a step of forming shallow trench isolation structures in the substrate. The field plate structure is formed on the substrate between adjacent shallow trench isolation structures. In an embodiment, the adjacent shallow trench isolation structures include a first shallow trench isolation structure having a lower surface in contact with the drift region, and a second shallow trench isolation structure having a lower surface in contact with the body region. In the present disclosure, the shallow trench isolation structures may be formed by a process commonly used by those skilled in the art.

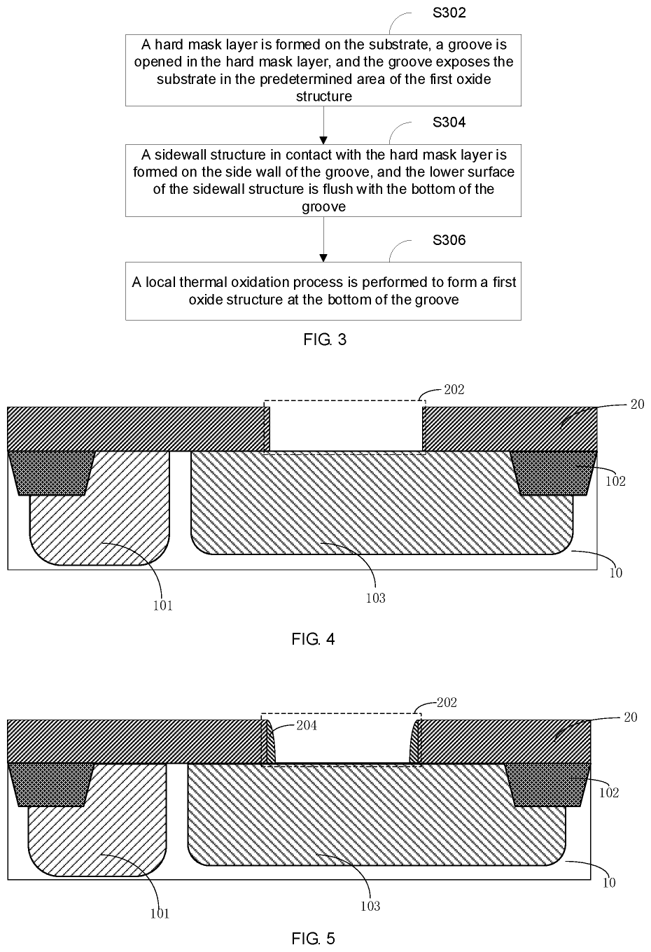

FIG. 3 is a schematic diagram showing the process of forming a first oxide structure in a drift region according to an embodiment.

In an embodiment, the first oxide structure includes a local oxidation of silicon (LOCOS) isolation structures, as shown in FIG. 3, and step S202 includes:

S302, a hard mask layer is formed on the substrate, a groove is opened in the hard mask layer, and the groove exposes the substrate in the predetermined area of the first oxide structure.

FIG. 4 is a cross-sectional view of the device in an embodiment in which the hard mask layer has been formed on the substrate.

As shown in FIG. 4, first, a substrate 10 is obtained and shallow trench isolation structures 102 are formed in the substrate 10, and second, a body region and a drift region 103 adjacent to each other are formed between adjacent shallow trench isolation structures 102 in the substrate. Next, a hard mask layer 20 is formed on the substrate 10 between the adjacent shallow trench isolation structures 102, and a groove 202 located above the drift region 103 is opened in the hard mask layer 20. The groove 202 exposes the substrate (drift region 103) in the predetermined area of the first oxide structure.

Specifically, a hard mask film is formed on the surface of the substrate, and then the hard mask film in the predetermined area of the first oxide structure located above the drift region 103 is removed by a photolithography and/or etching process, to obtain the hard mask layer 20 consisting of the remaining hard mask film. The groove 202 is formed at the location of the predetermined area of the first oxide structure.

In an embodiment, the hard mask layer 20 includes an oxide layer, a nitride layer, or a stacked structure of the two. As an example, in an embodiment, the hard mask layer 20 is a silicon nitride mask layer.

S304, a sidewall structure in contact with the hard mask layer is formed on the side wall of the groove, and the lower surface of the sidewall structure is flush with the bottom of the groove.

FIG. 5 is a cross-sectional view of the device in an embodiment in which the sidewall structure has been formed.

As shown in FIG. 5, a sidewall structure 204 in contact with the hard mask layer 20 is formed on the side wall of the groove 202. Specifically, first, a sidewall film is formed on the substrate 10, the sidewall film covering the surface of the predetermined area of the first oxide structure (drift region 103 exposed at the bottom of the groove 202) and extending along sidewalls of the groove 202 to the surface of the hard mask layer 20; then, the excess sidewall film is removed by a photolithography process and/or a dry etching process to obtain a sidewall structure 204 consisting of a sidewall film covering the sidewalls of the groove 202, with the lower surface of the sidewall structure 204 flush with the bottom of the groove 202 (the upper surface of the drift region 103). By forming the sidewall structure 204, the amount of oxygen entering below the hard mask layer 20 adjacent to the sidewalls of the groove 202 can be reduced during subsequent local thermal oxidation processes. This reduces the length of the bird's beak of the formed local silicon isolation oxide structure (first oxide structure), eliminating the impact of the bird's beak length on the pitch of the entire device.

In an embodiment, the sidewall structure 204 is a silicon nitride structure. In practice, sidewall structures 204 made of different materials can be selected as needed.

S306, a local thermal oxidation process is performed to form a first oxide structure at the bottom of the groove.

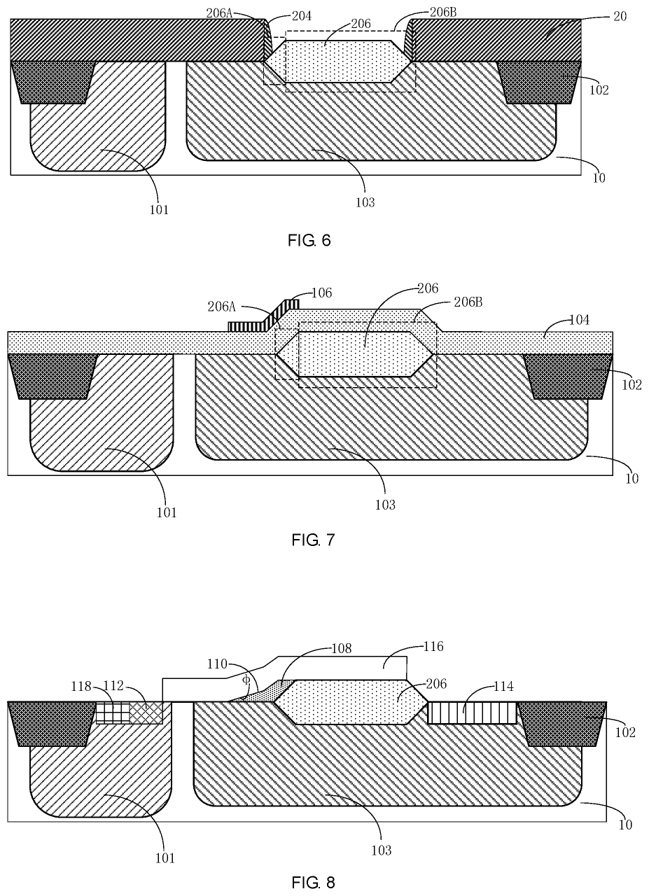

FIG. 6 is a cross-sectional view of the device in an embodiment in which the first oxide structure has been formed.

As shown in FIG. 6, after forming the sidewall structure 204, a local thermal oxidation process is performed to form a LOCOS structure with a short bird's beak (local silicon isolation structure), i.e., the first oxide structure 206, at the bottom of the groove 202 (the predetermined area of the first oxide structure). The first oxide structure 206 includes a first end portion 206A close to the body region 101 and a second end portion 206B away from the body region 101. The thickness of the first end portion 206A increases sequentially from the portion close to the body region 101 toward the location of the second end portion 206B. In the subsequent process, a source region is formed in the body region 101 on the side close to the first end portion 206A, and a drain region is formed in the drift region 103 on the side close to the second end portion 206B. The thickness of the second end portion 206B on the side close to the first end portion 206A is a preset value, i.e., the first end portion 206A is near the body region 101, and the junction (intersection position) of the first end portion 206A and the second end portion 206B is a position where the thickness of the first oxide structure 206 changes from less than a preset value to a preset value; then, the hard mask layer 20 and the sidewall structure 204 on the substrate 10 are removed.

S204, a second oxide structure is formed on the upper surface of the drift region on the side close to the body region. The second oxide structure extends along the upper surface of the first end portion to the junction of the first end portion and the second end portion.

A second oxide structure 108 is formed on the upper surface of the drift region 103 on the side close to the body region 101. The second oxide structure 108 extends along the upper surface of the first end portion 206A to the position where the thickness of the first oxide structure 206 varies from less than a preset value to a preset value. The above-mentioned upwardly extending inclined surface is the upper surface of the second oxide structure near the body region, and the angle between the inclined surface and the lower surface of the end of the field plate structure near the body region is not less than 30 degrees and not more than 60 degrees.

In an embodiment, step S204 includes: in a first step, an oxide film 104 is formed on the upper surface of the substrate 10; in a second step, a photoresist mask layer 106 is formed on the oxide film 104, and the photoresist mask layer 106 covers the oxide film 104 in a predetermined region of the second oxide structure; in a third step, a wet etching process is performed to remove the excess oxide film 104 to obtain a second oxide structure 108 consisting of the remaining oxide film 104 in the predetermined region of the second oxide structure.

FIG. 7 is a cross-sectional view of the device in an embodiment in which the photoresist mask layer has been formed. FIG. 8 is a cross-sectional view of the device in an embodiment in which the second oxide structure has been formed.

As shown in FIGS. 7-8, first, an oxide film 104 is formed on the upper surface of the substrate 10. Next, a photoresist mask layer 106 is formed on the oxide film 104. The photoresist mask layer 106 covers the oxide film 104 in a predetermined region of the second oxide structure, and the second oxide structure is located on the side close to the body region 101. The projection of the photoresist mask layer 106 on the substrate 10 surrounds the first end portion 206A. The projection of the endpoint of the photoresist mask layer 106 near the first oxide structure 206 on the substrate 10 is aligned with the junction of the first end portion 206A and the second end portion 206B. The projection of the endpoint of the photoresist mask layer 106 away from the first oxide structure 206 on the substrate 10 is located on the drift region 103 between the body region 101 and the first oxide structure 206, that is, the projection of the endpoint of the photoresist mask layer 106 away from the first oxide structure 206 on the substrate 10 has a certain distance from the first end portion 206A. Next, a wet etching process is performed to remove the excess oxide film 104 to obtain a second oxide structure 108 consisting of the remaining oxide film 104 in the predetermined region of the second oxide structure. The second oxide structure 108 covers the upper surface of the substrate 10 and extends along the upper surface of the first end portion 206A to the junction of the first end portion 206A and the second end portion 206B. That is, the second oxide structure 108 covers a portion of the drift region 103 near the body region 101 and also covers the upper surface of the first end portion 206A, and the sum of the thickness of the portion of the second oxide structure 108 covering the upper surface of the first end portion 206A and the thickness of the first end portion 206A is not greater than the thickness of the flat area of the second end portion 206B (i.e., the area of the first oxide structure where the thickness remains constant), i.e., the sum of the thickness of the portion of the second oxide structure 108 covering the first end portion 206A and the thicknesses of the first end portion 206A is not greater than a preset value. Thus, the thickness of the field plate structure gradually increases, and a gradient electric field distribution can be obtained on the polysilicon gate structure 116 formed on the field plate structure. The upper surface 110 of the second oxide structure 108 near the body region is the inclined surface of the field plate structure, and the angle φ between this upper surface 110 and the upper surface of the substrate 10 (the intersection interface between the field plate structure and the upper surface of the substrate 10) is greater than or equal to 30 degrees and less than or equal to 60 degrees. The second oxide structure 108 and the first oxide structure 206 together constitute the field plate structure. By adjusting the adhesion of the photoresist mask layer 106 to the oxide film 104, and the etching rate of the wet etching process and the etching liquid, the angle φ can be adjusted to achieve the effect of adjusting the slope of the thickness change of the field plate structure along the direction from the body region to the drift region, and thus adjusting the performance of the device.

In other embodiments, the portion of the second oxide structure 108 that overlaps with the first oxide structure 206 (i.e., the portion of the second oxide structure 108 covering the upper surface of the first end portion 206A) can be adjusted according to the morphology of the first oxide structure 206.

By covering the second oxide structure 108 on the first end portion 206A of the first oxide structure 206, the slope of the thickness change of the field plate structure including the first oxide structure 206 and the second oxide structure 108 can be adjusted, to form a field plate structure with a gently varying thickness as compared to that using only the first oxide structure 206.

In an embodiment, both the first oxide structure 206 and the second oxide structure 108 are silicon dioxide structures.

In an embodiment, the oxide film 104 is formed on the upper surface of the substrate 10 by a chemical vapor deposition process.

In an embodiment, the oxide film 104 has a thickness of not less than 300 A and not greater than 1500 Å.

In an embodiment, the method for preparing the laterally diffused metal oxide semiconductor device further includes:

In a first step, a source region having a second conductivity type is formed in the upper layer of the body region 101; and in a second step, a polysilicon gate is formed on the field plate structure, the polysilicon gate extending along the field plate structure to cover the substrate between the source region and the field plate structure.

As shown in FIG. 8, a doping process is performed to form a source region 112 with a second conductivity type in the upper layer of the body region 101, and a drain region 114 with a second conductivity type is formed in the drift region 103 between the first oxide structure 206 and a shallow trench isolation structure 102 (i.e., the first shallow trench isolation structure having a lower surface contact with the drift region). One end of the drain region 114 is in contact with the first oxide structure 206, and the other end of the drift region 114 is in contact with this shallow trench isolation structure 102. Next, a polysilicon gate structure 116 is formed on the field plate structure. The polysilicon gate structure 116 extends along the field plate structure to cover the substrate 10 between the source region 112 and the field plate structure, i.e., the polysilicon gate structure 116 extends along the field plate structure to cover the substrate 10 between the source region 112 and the second oxide structure 108.

In an embodiment, the method for preparing the laterally diffused metal oxide semiconductor device further includes a step of forming a heavily-doped region 118 of a first conductivity type in the body region 101 between the source region 112 and a shallow trench isolation structure 102 (i.e., the second shallow trench isolation structure having a lower surface contact with the body region).

In an embodiment, the method for preparing the laterally diffused metal oxide semiconductor device further includes a step of forming a gate oxide layer and a metal interconnecting layer.

It should be understood that although the steps in the flowchart of FIG. 1 are displayed in sequence according to the direction of the arrows, these steps are not necessarily executed in the order indicated by the arrows. Unless explicitly stated, there is no strict order restriction on the execution of these steps, and these steps can be executed in any other orders. Moreover, at least some of the steps in FIG. 1 may include multiple steps or stages. These steps or stages do not necessarily have to be completed at the same time but can be executed at different times. The execution order of these steps or stages does not necessarily have to be sequential but can be executed alternately or in turn with other steps or at least part of the steps or stages in other steps.

As shown in FIG. 8, in an embodiment, the present disclosure further provides a laterally diffused metal oxide semiconductor device, which includes a substrate 10, a body region 101, a drift region 103, a field plate structure, and a drain region 114.

The substrate 10 may be undoped single monocrystalline silicon, impurity-doped monocrystalline silicon, silicon on insulator (SOI), stacked silicon on insulator (SSOI), stacked silicon germanium on insulator (S—SiGeOI), silicon germanium on insulator (SiGeOI), or germanium on insulator (GeOI). As an example, the material of the substrate 10 is monocrystalline silicon.

The body region 101 has a first conductivity type and is formed in the substrate 10.

The drift region 103 has a second conductivity type, is formed in the substrate 10 and may be adjacent to the body region 101. The second conductivity type is opposite to the first conductivity type. When the first conductivity type is P type, the second conductivity type is N type; when the first conductivity type is N type, the second conductivity type is P type. In this embodiment, the first conductivity type is P type, and the second conductivity type is N type.

The field plate structure is formed on the drift region 103. The lower surface of an end of the field plate structure near the body region 101 is flush with the upper surface of the substrate 10, and the end of the field plate structure near the body region 101 also has an upwardly extending inclined surface 110. The lower surface of an end of the field plate structure away from the body region 101 is lower than the upper surface of the substrate 10. The thickness of the field plate structure from the end near the body region 101 to the end far from the body region 101 gradually increases to a preset value.

The drain region 114 has a second conductivity type, is formed in the upper layer of the drift region 103 and is in contact with the end of the field plate structure away from the body region 101.

In an embodiment, the angle φ between the inclined surface 110 and the lower surface of the end of the field plate structure near the body region 101 is not less than 30 degrees and not more than 60 degrees. By adjusting the angle φ, it is possible to adjust the change rate of the thickness of the field plate structure from the body region 101 to the drift region 103, and thus adjusting the performance of the device.

In an embodiment, the field plate structure includes a first oxide structure 206 and a second oxide structure 108.

The first oxide structure 206 is an end of the field plate structure close to the drain region 114 and formed on the drift region 103. The upper surface of the first oxide structure 206 is not lower than the upper surface of the substrate 10. Along the direction from the body region 101 to the drift region 103, the first oxide structure 206 sequentially includes a first end portion and a second end portion. The thickness of the first oxide structure 206 gradually increases to a preset value from the first end portion toward the second end portion. The junction of the first end portion 206A and the second end portion 206B is a position where the thickness of the first oxide structure 206 changes from less than the preset value to the preset value.

The second oxide structure 108 is formed on the upper surface of the drift region 103 on the side close to the body region 101, and extends along the upper surface of the first end portion to the position where the first end portion and the second end portion meet. The inclined surface 110 is the upper surface of an end of the second oxide structure near the body region.

In an embodiment, the thickness of the second oxide structure 108 is not greater than 1500 Å.

In an embodiment, the first oxide structure 206 includes a local silicon isolation oxide structure, which is made by a recess process.

In an embodiment, the laterally diffused metal oxide semiconductor device further includes a source region 112, a polysilicon gate 116, and shallow trench isolation structures 102.

The source region 112 has a second conductivity type, and is formed in the upper layer of the body region 101.

The polysilicon gate 116 is formed on the field plate structure and extends along the field plate structure to cover the substrate 10 between the source region 112 and the field plate structure.

The shallow trench isolation structures 102 are formed in the substrate 10. One of the shallow trench isolation structures 102 is in contact with the drain region 114, and a portion of the lower surface of this shallow trench isolation structure 102 is in contact with the drift region 103.

In the laterally diffused metal oxide semiconductor device, a field plate structure is formed on the drift region. The lower surface of an end of the field plate structure near the body region is flush with the upper surface of the substrate, and the end of the field plate structure near the body region also has an upwardly extending inclined surface. The lower surface of an end of the field plate structure away from the body region is lower than the upper surface of the substrate. The thickness of the field plate structure gradually increases to a preset value from the end near the body region to the end far from the body region. By providing a field plate structure with the end near the body region having a lower surface flush with the upper surface of the substrate and having an upwardly extending inclined surface, and gradually increasing the thickness of the field plate structure to a preset value from the end near the body region to the end away from the body region, a field plate structure with gradually increasing thickness is formed at the position of the JFET region without increasing the length of the field plate structure whose lower surface is below the upper surface of the substrate (without increasing the pitch of the LDMOS device), thus improving the reliability of the device while improving the electric field distribution on the device surface.

In this specification, the description with reference to the terms “some embodiments”, “other embodiments” “ideal embodiments”, etc., means that a specific feature, structure, material, or characteristic described in combination with the embodiment or example is included in at least one embodiment or example of the present disclosure. In this specification, schematic representations of the above terms do not necessarily refer to the same embodiment or example.

The technical features of the above described embodiments can be combined in any number of ways. For the sake of brevity, not all possible combinations of each technical feature of the above embodiments have been described, however, as long as these combinations of technical features are not contradictory, they should be considered to be within the scope of the present disclosure.

The above embodiments only express several embodiments of the present disclosure. Their description is relatively specific and detailed, but it should not be understood as a limitation on the protection scope of the present disclosure. It should be noted that for those skilled in the art, variations and improvements may be made without departing from the spirit of the present disclosure, these variations and improvements are within the protection scope of the present disclosure. Therefore, the protection scope of the present disclosure shall be subject to the scope defined in claims.

What is claimed is:

1. A laterally diffused metal oxide semiconductor device, comprising:
a substrate;
a body region, having a first conductivity type and being formed in the substrate;
a drift region, having a second conductivity type, being formed in the substrate and being adjacent to the body region, wherein the second conductivity type is opposite to the first conductivity type;
a field plate structure, formed on the drift region, wherein a lower surface of an end of the field plate structure close to the body region is flush with an upper surface of the substrate, and the end of the field plate structure close to the body region also has an upwardly extending inclined surface; wherein a lower surface of an end of the field plate structure away from the body region is lower than the upper surface of the substrate; wherein a thickness of the field plate structure gradually increases to a preset value along a direction from the end of the field plate structure close to the body region to the end of the field plate structure away from the body region; and
a drain region, having a second conductivity type, being formed in an upper layer of the drift region, and being in contact with the end of the field plate structure away from the body region.

2. The laterally diffused metal oxide semiconductor device according to claim 1, wherein an angle between the inclined surface and the lower surface of the end of the field plate structure close to the body region is not less than 30 degrees and not more than 60 degrees.

3. The laterally diffused metal oxide semiconductor device according to claim 1, wherein the field plate structure comprises:
a first oxide structure, wherein the first oxide structure is the end of the field plate structure away from the body region, wherein the first oxide structure is formed on the drift region, and an upper surface of the first oxide structure is not lower than the upper surface of the substrate; wherein along a direction from the body region to the drift region, the first oxide structure sequentially comprises a first end portion and a second end portion; wherein a thickness of the first oxide structure gradually increases to a preset value from the first end portion toward the second end portion; and
a second oxide structure, wherein the second oxide structure is formed on an upper surface of an end of the drift region close to the body region, and extends along an upper surface of the first end portion to a junction of the first end portion and the second end portion; wherein the inclined surface is an upper surface of an end of the second oxide structure close to the body region.

4. The laterally diffused metal oxide semiconductor device according to claim 3, wherein a thickness of the second oxide structure is not greater than 1500 Å.

5. The laterally diffused metal oxide semiconductor device according to claim 3, wherein the first oxide structure includes a local silicon isolation oxide structure, which is made by a recess process.

6. The laterally diffused metal oxide semiconductor device according to claim 1, further comprising:
a source region, wherein the source region has a second conductivity type and is formed in an upper layer of the body region.
a polysilicon gate, wherein the polysilicon gate is formed on the field plate structure and extends along the field plate structure to cover a portion of the substrate between the source region and the field plate structure; and
shallow trench isolation structures, wherein the shallow trench isolation structures are formed in the substrate; wherein a first shallow trench isolation structure of the shallow trench isolation structures is in contact with the drain region, and a portion of a lower surface of the first shallow trench isolation structure is in contact with the drift region.

7. A method for preparing a laterally diffused metal oxide semiconductor device, comprising:
providing a substrate;
forming a body region and a drift region that are adjacent to each other in the substrate, wherein the body region has a first conductivity type, and the drift region has a second conductivity type opposite to the first conductivity type;
forming a field plate structure on the drift region, wherein a lower surface of an end of the field plate structure close to the body region is flush with an upper surface of the substrate, and the end of the field plate structure close to the body region has an upwardly extending inclined surface; wherein a lower surface of an end of the field plate structure away from the body region is lower than the upper surface of the substrate; wherein a thickness of the field plate structure gradually increases to a preset value along a direction from the end of the field plate structure close to the body region to the end of the field plate structure away from the body region; and
forming a drain region of a second conductivity type in an upper layer of the drift region, wherein the drain region is in contact with the end of the field plate structure away from the body region.

8. The method according to claim 7, wherein the forming of the field plate structure on the drift region comprises:
forming a first oxide structure on the drift region, wherein along a direction from the body region to the drift region, the first oxide structure sequentially comprises a first end portion and a second end portion, and a thickness of the first oxide structure gradually increases to a preset value from the first end portion toward the second end portion; and
forming a second oxide structure on an upper surface of an end of the drift region close to the body region, wherein the second oxide structure extends along an upper surface of the first end portion to a junction of the first end portion and the second end portion; wherein
the first oxide structure is the end of the field plate structure away from the body region, and the inclined surface is an upper surface of an end of the second oxide structure close to the body region; wherein an angle between the inclined surface and the lower surface of the end of the field plate structure close to the body region is not less than 30 degrees and not more than 60 degrees.

9. The method according to claim 8, wherein the first oxide structure comprises a local silicon isolation oxide structure, and the forming of the first oxide structure on the drift region comprises:
forming a hard mask layer on the substrate, and forming a groove in the hard mask layer, wherein the groove exposes a portion of the substrate where a predetermined area of the first oxide structure is located;
forming a sidewall structure on sidewalls of the groove, wherein the sidewall structure is in contact with the hard mask layer, and a lower surface of the sidewall structure is flush with a bottom of the groove; and
forming the first oxide structure at the bottom of the groove by performing a local thermal oxidation process.

10. The method according to claim 8, wherein the forming of the second oxide structure on the upper surface of the end of the drift region close to the body region comprises:
forming an oxide film on the upper surface of the substrate;
forming a photoresist mask layer on the oxide film, wherein the photoresist mask layer covers a portion of the oxide film where a predetermined region of the second oxide structure is located; and
removing excess oxide film by performing a wet etching process, to obtain the second oxide structure consisting of the remaining oxide film in the predetermined region of the second oxide structure.

11. The method according to claim 10, wherein the oxide film has a thickness of not less than 300 Å and not greater than 1500 Å.

12. The method according to claim 7, further comprising:
forming shallow trench isolation structures in the substrate, wherein a first shallow trench isolation structure of the shallow trench isolation structures is in contact with the drain region, and a portion of a lower surface of the first shallow trench isolation structure is in contact with the drift region;
forming a source region with a second conductivity type in an upper layer of the body region; and
forming a polysilicon gate on the field plate structure, wherein the polysilicon gate extends along the field plate structure to cover a portion of the substrate between the source region and the field plate structure.
